(19) United States
(12) Patent Application Publication
(10) Pub. No.: US 2012/0126304 A1
(43) Pub. Date: May 24, 2012

(54) FLOATING GATE TYPE SEMICONDUCTOR MEMORY DEVICE AND METHOD OF MANUFACTURING THE SAME

(75) Inventor: Kyoung Rok HAN, Yongin-si (KR)

(73) Assignee: HYNIX SEMICONDUCTOR INC., Icheon-si (KR)

(21) Appl. No.: 13/298,498

(22) Filed: Nov. 17, 2011

(30) Foreign Application Priority Data
Nov. 18, 2010 (KR) 10-2010-0114936

(51) Int. Cl. H01L 29/788; H01L 21/28

(52) U.S. Cl. 257/316; 438/591; 257/E29.3; 257/E21.19

(57) ABSTRACT

A floating gate type semiconductor memory device includes a tunnel insulating layer, a floating gate formed on the tunnel insulating layer, a control gate electrode formed over the floating gates, a charge blocking layer formed between the floating gates and the control gate electrode, and a barrier layer formed in one or more areas of an area between the charge blocking layer and the control gate electrode and an area between the floating gate and the charge blocking layer and on an area corresponding to the sidewall of the floating gate.

### CROSS-REFERENCE TO RELATED APPLICATION

Priority is claimed to Korean patent application number 10-2010-0114936 filed on Nov. 18, 2010, the entire disclosure of which is incorporated by reference herein.

### BACKGROUND

Exemplary embodiments relate generally to a semiconductor device and a method of manufacturing the same and, more particularly, to a floating gate type nonvolatile memory device and a method of manufacturing the same.

Nonvolatile memory devices known for retaining data with no supply of power can be categorized based on the type of data storage method of a charge trap type or a floating gate type. The charge trap type nonvolatile memory device stores data by storing electric charges in a charge trap layer in the nonvolatile memory device. The floating gate type nonvolatile memory device stores data by storing electric charges in a floating gate in the nonvolatile memory device.

The parts that make up a floating gate type nonvolatile memory device include a tunnel insulating layer, a floating gate, a charge blocking layer, and a control gate electrode formed over a substrate. The tunnel insulating layer functions as an energy barrier for Fowler-Nordheim (F-N) tunneling. The floating gate functions as a substantial data depository for storing electric charges. Furthermore, the charge blocking layer functions as an isolation layer for preventing electric charges in the floating gate from moving to the control gate electrode.

In a floating gate type nonvolatile memory device, the F-N tunneling effect allows the electric charges in a channel to be injected into the floating gate through the tunnel insulating layer when a program voltage is supplied to the control gate electrode. The threshold voltage of the memory cell would then be raised by the electric charges injected into the floating gate, and, by reading the threshold voltage, the data content of the memory cell can be interpreted as ‘0’.

Reducing the cell areas for higher degree of integration could lead to severe degradation of the program characteristics of a nonvolatile memory device, due to the reduction in the coupling ratio due to the reduction in the cell area. This type of coupling ratio reduction may not be problematic for a charge trap type nonvolatile memory device that stores data using the charge trap layer; however, for a floating gate type nonvolatile memory device that stores data using a floating gate, reduced coupling ratio will lead to degradation of the program characteristics.

FIG. 1 shows the simulated coupling ratio changes related to the cell area reduction in a known floating gate type nonvolatile memory device. In FIG. 1, the X axis shows the thickness of a charge blocking layer, and the Y axis shows the coupling ratio. Furthermore, A, B, and C represent the degree of high integration. The degree of high integration is increased from A to B to C (that is, A<B<C).

As can be understood from FIG. 1, higher degree of integration leads to more reduction of the coupling ratio. Although the coupling ratio can be somewhat improved by reducing the charge blocking layer thickness, this improvement is not enough to sufficiently prevent the severe degradation of the coupling ratio that may occur due to the increased degree of high integration.

A few techniques are known for improving the coupling ratio of the floating gate type nonvolatile memory device but are not considered to be satisfactory.

First is to increase the height of the floating gate or to reduce the thickness of the tunnel insulating layer. However, increasing the height of the floating gate would make it difficult to increase the degree of high integration of the memory devices. Likewise, reducing the thickness of the tunnel insulating layer may cause the data retention characteristics and the cycling characteristics of the memory device to be degraded because electric charge leakage may occur.

Second is to reduce the thickness of the charge blocking layer. However, reduction of the thickness of the charge blocking layer will lead to reduction in the charge storage capability and lowered insulating breakdown voltage due to increase in the leakage current between the floating gate and the control gate electrode. Accordingly, there is a difficulty in performing a program operation using a high voltage.

In general, a charge blocking layer has an ONO stack structure of a lower oxide layer, a nitride layer in the middle, and an upper oxide layer. If the thickness of the charge blocking layer is reduced to increase the coupling ratio, then the charge blocking layer would not play its role well when a program operation is performed. That is, when the program operation is performed, (1) the electric charges stored in the floating gate are moved to the charge blocking layer and then are trapped in the nitride layer of the charge blocking layer; or (2) the electric charges are moved to the control gate electrode through the charge blocking layer, so that the threshold voltage of a memory cell is not properly increased.

This is known as a program saturation phenomenon. Even if a high program voltage is supplied to the control gate electrode, the threshold voltage of a memory cell does not rise at a certain value or higher. Furthermore, since the leakage current is further increased with a reduction in the thickness of the charge blocking layer, a program voltage (that is, a program saturation voltage) at which the program saturation phenomenon is generated is further lowered.

FIGS. 2A and 2B show the energy band diagrams of the charge blocking layer of a known floating gate type nonvolatile memory device. In particular, FIGS. 2A and 2B show an example in which the charge blocking layer is formed of a lower oxide layer, a nitride layer, and an upper oxide layer (O/N/O).

FIG. 2A shows an example according to which electric charges stored in a floating gate are moved through the lower oxide layer and trapped in the nitride layer. The trapped charges may move to a control gate electrode through the upper oxide layer. Here, the discharge of the electric charges from the floating gate may be temporarily reduced to some extent because the bandgap energy of the lower oxide layer is increased by the electric charges trapped in the nitride layer.

FIG. 2B shows an example according to which an electric field applied to the charge blocking layer is increased by supplying a higher voltage to the control gate electrode. Electric charges stored in the floating gate are moved to the control gate electrode by means of the electric field applied to the charge blocking layer. Furthermore, holes are injected from the control gate electrode to the charge blocking layer. The injected holes are moved to the nitride layer through the upper oxide layer and then recombined with the electric charges trapped in the nitride layer. Accordingly, the bandgap energy of the lower oxide layer is lowered again, and the electric charges stored in the floating gate continue to be discharged to the control gate electrode. That is, a program saturation phenomenon is generated, and so a program saturation voltage is gradually reduced.

Furthermore the program saturation phenomenon may become severe by a further reduction in the thickness of the charge blocking layer. Consequently, although the coupling ratio may be increased by reducing the thickness of the charge blocking layer, the program saturation phenomenon may make it difficult to perform a multi-level cell program requiring a higher program voltage.

In addition, the interval between neighboring memory cells is reduced because of a reduction in the cell area. For this reason, in order to secure a gap-fill margin, method of reducing the thickness of the charge blocking layer is known. However, since the leakage current is further increased according to a reduction in the thickness of the charge blocking layer as describe above, a program saturation voltage is further lowered.

### BRIEF SUMMARY

Exemplary embodiments relate to a floating gate type nonvolatile memory device and a method of manufacturing the same, which improve the coupling ratio and also provide a structure suitable for preventing the program saturation phenomenon.

A floating gate type nonvolatile memory device according to an embodiment of the present disclosure includes a tunnel insulating layer, floating gates formed on the tunnel insulating layer, a control gate electrode formed over the floating gates, a charge blocking layer interposed between the floating gates and the control gate electrode, and a barrier layer interposed between the charge blocking layer and the control gate electrode or between the floating gates and the charge blocking layer.

Furthermore, a method of manufacturing a floating gate type nonvolatile memory device according to an embodiment of the present disclosure includes forming a tunnel insulating layer and conductive patterns for floating gates over a substrate, forming a charge blocking layer following an entire surface of results in which the conductive patterns for floating gates are formed, forming a conductive layer for a control gate electrode over the charge blocking layer, wherein a barrier layer is formed after forming the conductive patterns for floating gates or after forming the charge blocking layer.

### BRIEF DESCRIPTION OF THE DRAWINGS

FIG. 1 is a simulation graph showing a change of the coupling ratio according to a reduction in the cell area of a known floating gate type nonvolatile memory device;

FIGS. 2A and 2B show the energy band diagrams of the charge blocking layer of a known floating gate type nonvolatile memory device;

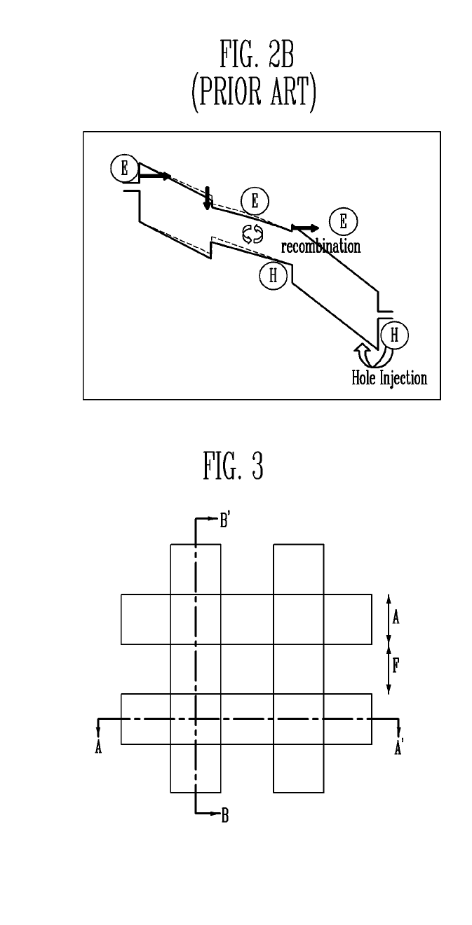

FIG. 3 is a layout diagram of the floating gate type nonvolatile memory device according to an exemplary embodiment of the present invention;

FIGS. 4A to 7B are process sectional views illustrating a method of manufacturing a floating gate type nonvolatile memory device according to an exemplary embodiment of the present invention;

FIGS. 8A and 8B are cross-sectional views showing a floating gate type nonvolatile memory device according to an embodiment of the present invention;

FIGS. 9A and 9B are cross-sectional views showing a floating gate type nonvolatile memory device according to an embodiment of the present invention;

FIGS. 10A and 10B are cross-sectional views showing a floating gate type nonvolatile memory device according to an embodiment of the present invention;

FIGS. 11A and 11B are cross-sectional views showing a floating gate type nonvolatile memory device according to an embodiment of the present invention;

FIGS. 12A and 12B are cross-sectional views showing a floating gate type nonvolatile memory device according to an embodiment of the present invention;

FIG. 13 is a cross-sectional view illustrating a floating gate type nonvolatile memory device having a 3-D structure according to an embodiment of the present invention;

FIG. 14 is a graph showing the characteristics of materials which can be used as a barrier layer;

FIG. 15 shows an energy band diagram when the program operation of the floating gate type nonvolatile memory device is performed according to an exemplary embodiment of this disclosure; and

FIG. 16 is a graph showing a change in the threshold voltage of a memory cell when the program operation of the floating gate type nonvolatile memory device is performed according to an exemplary embodiment of this disclosure.

### DESCRIPTION OF EMBODIMENTS

Hereinafter, embodiments of the present invention will be described in detail with reference to the accompanying drawings. The figures are provided to allow those having ordinary skill in the art to understand the scope of the embodiments of the disclosure.

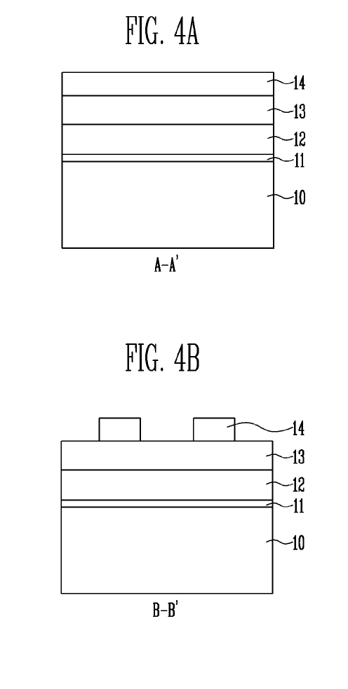

FIG. 3 is a layout diagram of a floating gate type nonvolatile memory device according to an exemplary embodiment of the present invention.

As shown in FIG. 3, an active region A is defined by isolation layers of a line form which are formed in field regions F. Bit lines are formed on a substrate in a first direction A-A′, and word lines are formed on the substrate in a second direction B-B′ crossing the first direction.

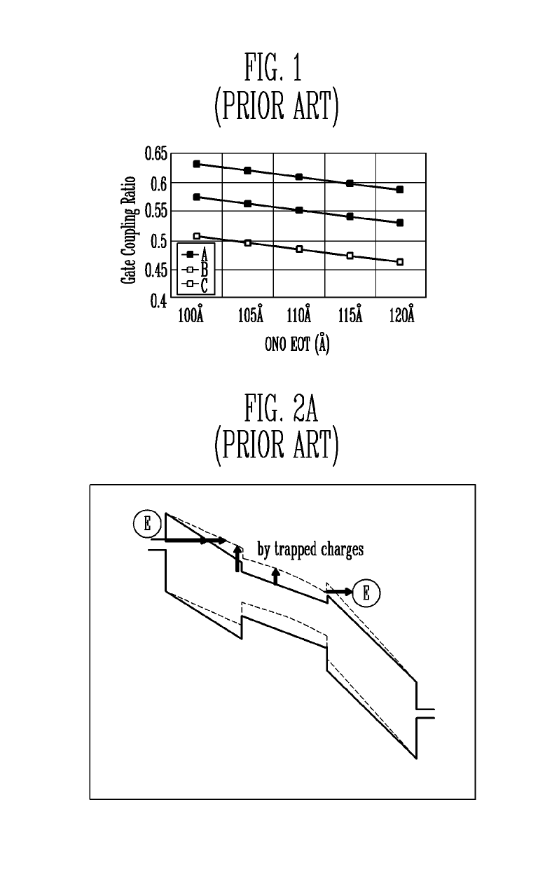

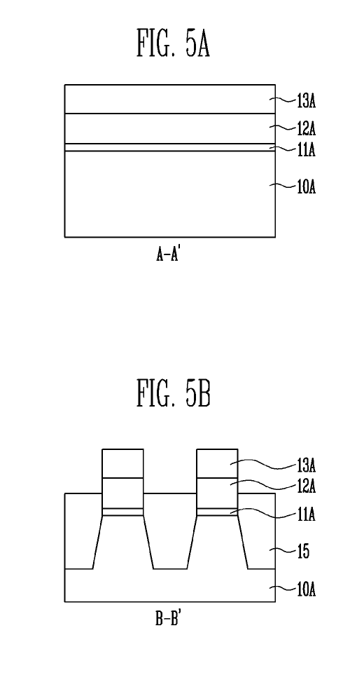

FIGS. 4A-4B, 5A-5B, 6A-6B, and 7A-7B are cross-sectional views illustrating a method of manufacturing the floating gate type nonvolatile memory device according to an exemplary embodiment of the present invention. FIGS. 4A, 5A, 6A, and 7A are the cross-sectional views in the first direction A-A′ of FIG. 1, and FIGS. 4B, 5B, 6C, and 7B are the cross-sectional views in the second direction B-B′ of FIG. 1.

Referring to FIGS. 4A and 4B, a tunnel insulating layer 11, which, for example, may be formed of an oxide layer, is formed over the substrate 10.

A conductive layer 12 for floating gates is formed on the tunnel insulating layer 11. Here, the conductive layer 12 may be formed of a polysilicon layer. A hard mask layer 13 is formed on the conductive layer 12. Here, the hard mask layer 13 may be formed of a nitride layer by taking etch selectivity with the previously formed layers.

An isolation mask pattern 14 of a line form which extends in the first direction is formed on the hard mask layer 13.

Referring to FIGS. 5A-5B, the hard mask layer 13, the conductive layer 12, and the tunnel insulating layer 11 are etched by using the isolation mask pattern 14 as an etch barrier. The substrate 10 is also etched to a certain depth to form isolation trenches. The isolation trenches are then filled with an insulating material to form isolation layers 15. Accordingly, the active regions and the field regions are defined. For example, the area of the floating gate coming in contact with a charge blocking layer (formed by a subsequent process) may be increased by controlling the Effective Field oxide Height (EFH) by etching the isolation layers 15 to a certain depth.

In the figures, the etched substrate is labeled with ‘10A’, the etched tunnel insulating layers are labeled with ‘11A’, conductive patterns for floating gates are labeled with ‘12A’, and hard mask patterns are labeled with ‘13A’.

As shown in FIGS. 6A-6B, the hard mask layer 13A is removed to expose the surface of the conductive pattern 12A for floating gates. Then, a charge blocking layer 16 is formed on the resultant surface including the conductive pattern 12A. It is noted that the charge blocking layer 16 may be formed without removing the hard mask patterns 13A. Further, prior to the formation of the charge blocking layer 16, the surface of the conductive patterns 12A for floating gates may be subjected to nitrification treatment process according to an embodiment of the present invention. The nitrification treatment process for the surface of the conductive patterns 12A may be performed using a thermal nitrification process or a plasma nitrification process. For example, the plasma nitrification process may be performed using argon (Ar) and nitrogen (N) gases of about 1/0.2 L under the conditions that temperature is about 400 to 600° C., pressure is 0.1 to 0.2 Torr, power is 1000 to 2000 W, and a concentration is about 15%.

The charge blocking layer 16 may be an ONO layer having the stack structure of a lower oxide layer, a nitride layer in the middle, and an upper oxide layer. In FIGS. 6A-6B, however, the charge blocking layer 16 (which may comprise the lower oxide layer, the nitride layer, and the upper oxide layer) are drawn with one layer, but it should be readily understood that the charge block layer 16 may comprise a plurality of layers. The lower oxide layer and the upper oxide layer may comprise silicon dioxide SiO₂, and the nitride layer may comprise silicon nitride Si₃N₄.

Next, a barrier layer 17 is formed on the charge blocking layer 16. The barrier layer 17 functions to prevent holes from being injected into the charge blocking layer 16 from the control gate electrode which is formed by a subsequent process. The barrier layer 17 may be made of a material having a higher valance band offset than the material of the charge blocking layer 16, in particular, the oxide layer. Alternatively, the barrier layer 17 may be made of a material having a higher dielectric constant than the material of the charge blocking layer 16, in particular, the oxide layer and the nitride layer. For example, the barrier layer 17 may be formed of an Al₂O₃ layer.

The barrier layer 17 may be formed according to an atomic layer deposition (ALD) method by using a Trimethyl-Aluminum (TMA) gas, an Ar gas, and an O₃ gas in a temperature range of 350 to 500° C.

Next, a thermal treatment process may be performed. The thermal treatment process may be performed in a temperature range of 700 to 1100° C. using a furnace or a rapid thermal annealing (RTA) method. The tissue of the barrier layer 17 becomes minute by means of the thermal treatment process, thereby cutting off the leakage current more efficiently. Alternatively, the thermal treatment process may be performed after a process of forming a conductive layer 18 for a control gate electrode.

As shown in FIGS. 7A-7B, the conductive layer 18 for a control gate electrode is formed on the entire structure in which the barrier layer 17 is formed. A control gate mask pattern (not shown), extended in the second direction, is formed on the conductive layer 18 for a control gate electrode.

The conductive layer 18 for a control gate electrode, the barrier layer 17, the charge blocking layer 16, the conductive patterns 12A for floating gates, and the tunnel insulating layer 11A are etched by using the control gate mask pattern (not shown) as an etch barrier. Accordingly, the gate patterns, each having the tunnel insulating layer 11B, the floating gate 12B, the charge blocking layer 16A, the barrier layer 17A, and the control gate electrode 18, are formed.

In an embodiment of the present invention, the tunnel insulating layer 11 and the conductive layer 12 for floating gates electrodes are formed over the substrate 10, and the conductive layer 12 for floating gates and the tunnel insulating layer 11 are patterned to form the isolation layers 15 has been described. Further, according to an embodiment of the present invention, the tunnel insulating layer and the conductive layer for floating gates may be formed after the isolation layers are formed in the substrate.

Furthermore, in an embodiment of the present invention, it is described as an example that the barrier layer 17 may be formed on the charge blocking layer 16. Yet according to an embodiment of the present invention, the barrier layer 17 may be formed on the areas corresponding to the sidewalls of the floating gate 12B. In addition, an additional oxide layer may be formed on the barrier layer 17. In order to form the barrier layer 17 on the areas corresponding to the sidewalls of the floating gate 12B, for example, the barrier layer 17 is formed the resultant surface after the charge blocking layer 16 is formed, and an etch process is then performed so that the barrier layer 17 remains on only the areas corresponding to the sidewalls of the floating gate 12B.

Furthermore, in an embodiment of the present invention, barrier layer the barrier layer 17 may be formed under the charge blocking layer 16.

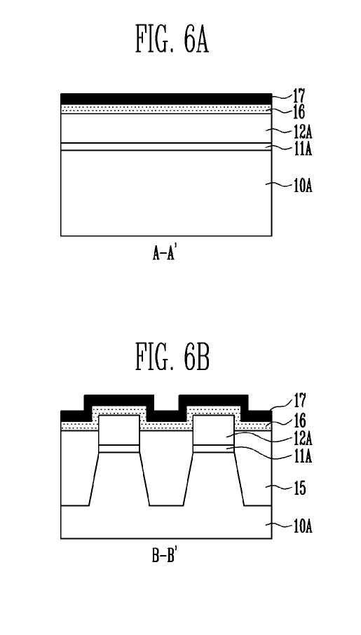

FIGS. 8A-8B are cross-sectional views showing a floating gate type nonvolatile memory device directed to showing a gate pattern structure according to an embodiment of the present invention. FIG. 8A is a cross-sectional view in the first direction A-A′, and FIG. 8B is a cross-sectional view in the second direction B-B′.

As shown in FIGS. 8A-8B, the floating gate type nonvolatile memory device according to an embodiment of the present invention includes, inter alia, tunnel insulating layers 21 on a substrate 20 in which source/drain regions S/D are formed. Floating gates 22 are formed on the tunnel insulating layers 21, and a control gate electrode 25 is formed on the floating gates 22. A charge blocking layer 23 is formed in between the floating gates 22 and the control gate electrode 25. A barrier layer 24 is formed on the resultant surface after the charge blocking layer 23 is formed on the floating gates 22, and thus the barrier layer 24 is formed between the charge blocking layer 23 and the control gate electrode 25. The barrier layer 24 could also be formed in between the floating gates 22 and the charge blocking layer 23. Isolation layer 26 is formed to define and insulate the active region. In the disclosure of the present application, the word “on” and “over” are not used to restrict the meaning in an exclusive manner. The meaning of “on” is not restricted only to something that is formed directly on top of another but also include the possibility of something that is formed on top of or “over” another, and the meaning of “over” does not exclude the possibility of something that is formed directly on top of or “on” another.

The charge blocking layer 23 may have a multiple layer stack structure. For example, the charge blocking layer 23 may include a lower oxide layer 23A, a nitride layer 23B, and an upper oxide layer 23C and formed to a thickness D2 of 30 Å to 300 Å. The lower oxide layer 23A may be formed to a thickness of 10 Å to 100 Å. The nitride layer 23B may be formed to a thickness of 10 Å to 100 Å, and the upper oxide layer 23C may be formed to a thickness of 10 Å to 100 Å. Furthermore, the barrier layer 24 may include Al₂O₃ and formed to a thickness of 1 Å to 50 Å. The total thickness of the charge blocking layer 23 and the barrier layers 24 (that is, D2+D3) may be formed to a thickness of 30 Å to 350 Å.

The barrier layer 24 separates the charge blocking layer 23 and the control gate electrode 25 as described above, such that the holes from the control gate electrode 25 are prevented from being transmitted through the barrier layer 24. In particular, the barrier layer 24 formed on the charge blocking layer 23 prevents the leakage current between the floating gates 22 and the control gate electrode 25, barrier layer even when the thickness of the charge blocking layer 23 is reduced.

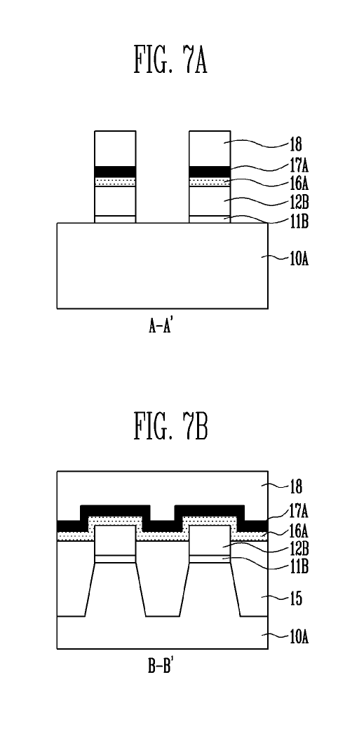

FIGS. 9A-9B are cross-sectional views showing a variation of a gate pattern structure of a floating gate type nonvolatile memory device according to an embodiment of the present invention. FIG. 9A is a cross-sectional view in the first direction A-A′, and FIG. 9B is a cross-sectional view in the second direction B-B′.

As shown in FIGS. 9A-9B, the floating gate type nonvolatile memory device according to an embodiment of the present invention includes, inter alia, a tunnel insulating layer 31 formed on a substrate 30 in which source/drain regions S/D are formed. Floating gates 32 are formed on the tunnel insulating layer 31, and a control gate electrode 35 formed on the floating gates 32. A charge blocking layer 33 is formed between the floating gates 32 and the control gate electrode 35 to cover the sidewalls and the upper portions of the floating gates 32, but a barrier layer 34 is formed only on the sidewall areas of the charge blocking layer 33 covering the floating gates 32.

The barrier layer 34 may be formed between the floating gates 32 and the charge blocking layer 33. For example, after forming the barrier layer 34 covering the floating gates 32, a dry etch process may be performed so that the barrier layer 34 remains on only the areas corresponding to the sidewalls of the floating gates 32. Alternatively, after forming the barrier layer 34 covering the charge blocking layer 33 formed on the floating gates 32, a dry etch process may be performed so that the barrier layer 34 remains on only the areas corresponding to the sidewalls of the floating gates 32.

If the barrier layer 34 is formed on only the areas corresponding to the sidewalls of the floating gates 32 as described above, the leakage current between the floating gates 32 and the control gate electrode 35 can be efficiently blocked. If the charge blocking layer 33 is formed using a deposition process, the charge blocking layer 33 having a relatively thin thickness is formed on the sidewalls of the floating gates 32. Accordingly, more leakage current is generated from the sidewalls of the floating gate 32. Therefore, if the barrier layer 34 is formed on only the sidewalls of the floating gates 32 as described above, the leakage current can be effectively blocked.

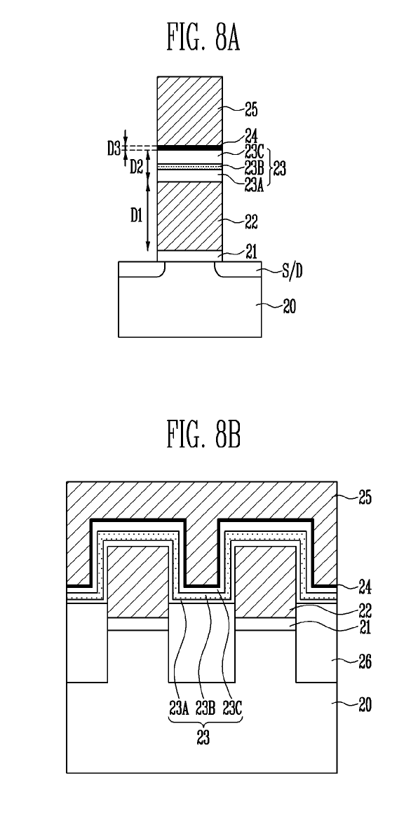

FIGS. 10A-10B are cross-sectional views showing a variation of a gate pattern structure of a floating gate type nonvolatile memory device according to an embodiment of the present invention. FIG. 10A is a cross-sectional view in the first direction A-A′, and FIG. 10B is a cross-sectional view in the second direction B-B′

As shown in FIGS. 10A-10B, the floating gate type nonvolatile memory device according to an embodiment of the present invention includes, inter alia, a tunnel insulating layer 41 formed on a substrate 40 in which source/drain regions S/D are formed. Floating gates 42 are formed on the tunnel insulating layer 41, and a control gate electrode 45 formed on the floating gates 42. A charge blocking layer 43 is formed between the floating gates 42 and the control gate electrode 45, and a barrier layer 44 is formed on the charge blocking layer 43. In addition, an oxide layer 47 is formed on the barrier layer 44.

Here, the oxide layer 47 may be formed using a deposition process or a thermal treatment process. The oxide layer 47 may have a thickness of 30 Å or less.

If the oxide layer 47 is further formed on the barrier layer 44 as described above, the leakage current between the floating gates 42 and the control gate electrode 45 can be effectively blocked.

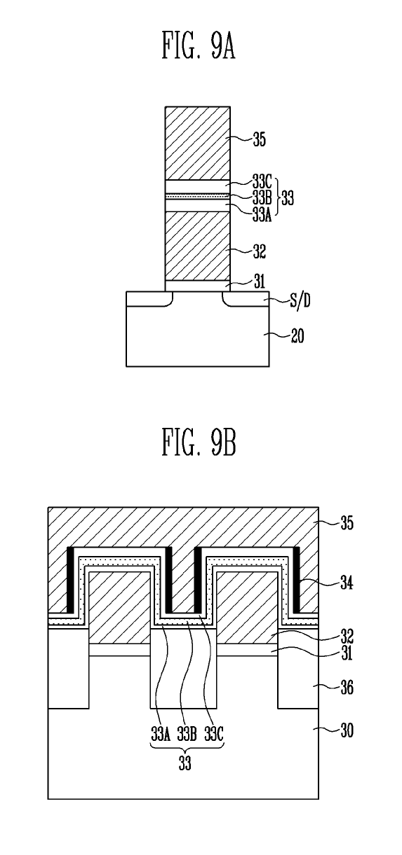

FIGS. 11A-11B are cross-sectional views showing variation of a gate pattern structure of a floating gate type nonvolatile memory device according to an embodiment of the present invention. FIG. 11A is a cross-sectional view in the first direction A-A′, and FIG. 11B is a cross-sectional view in the second direction B-B′.

The floating gate type nonvolatile memory device according to an embodiment of the present invention includes, inter alia, a tunnel insulating layer 51 formed on a substrate 50 in which source/drain regions S/D are formed. Floating gates 52 are formed on the tunnel insulating layer 51, and a control gate electrode 55 formed on the floating gates 52. A charge blocking layer 53 is formed between the floating gates 52 and the control gate electrode 55 to cover the sidewalls and the upper portions of the floating gates 52, but a barrier layer 54 is formed only on the sidewall areas of the charge blocking layer 53 covering the floating gates 52. In addition, a nitride layer 52A is formed between floating gates 52 and a charge blocking layer 53, for example, by performing nitrification treatment process on a surface of the floating gates 52.

The nitrification treatment process for nitrification of the surface of the floating gates 52 may be performed using a thermal nitrification process or a plasma nitrification process. For example, the plasma nitrification process may be performed using argon (Ar) and nitrogen (N) gases of about 1/0.2 L under the conditions that temperature is about 400 to 600° C., pressure is 0.1 to 0.2 Torr, power is 1000 to 2000 W, and a concentration of about 15%.

If, as described above, the nitride layer 52A is formed between the floating gates 52 and the charge blocking layer 53 by performing the nitrification treatment process on the surface of the floating gates 52, contamination due to the diffusion of materials from isolation layers 56 or the floating gates 52 can be prevented, thereby being capable of improving reliability of the device. Furthermore, a bird's beak can be prevented from occurring in a subsequent thermal treatment process. The nitrification treatment process for nitrification of the surface of the floating gates may also be applied to other embodiments.

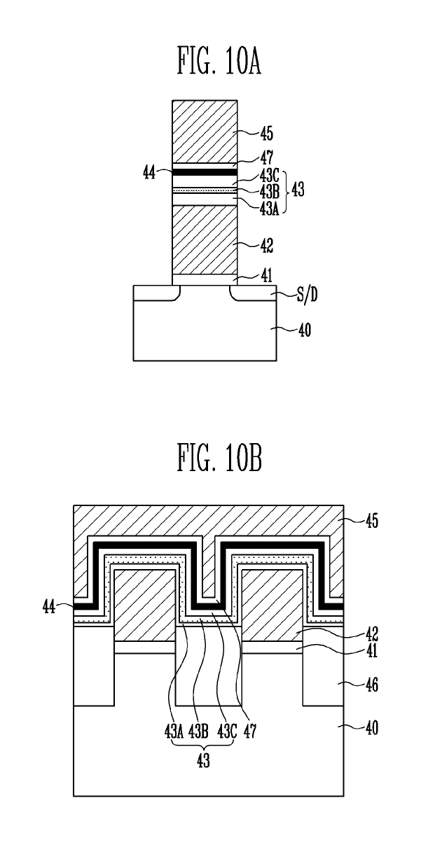

FIGS. 12A-12B are cross-sectional views showing a floating gate type nonvolatile memory device according to an embodiment of the present invention. FIG. 12A is a cross-sectional view in the first direction A-A′, and FIG. 12B is a cross-sectional view in the second direction B-B′.

The floating gate type nonvolatile memory device according to an embodiment of the present invention includes, inter alia, a tunnel insulating layer 61 formed on a substrate 60 in which source/drain regions S/D are formed. Floating gates 62 are formed on the tunnel insulating layer 61, and a control gate electrode 65 formed on the floating gates 62. A charge blocking layer 63 is formed between the floating gates 62 and the control gate electrode 65 to cover the sidewalls and the upper portions of the floating gates 62, but a barrier layer 64 is formed only on the sidewall areas of the charge blocking layer 63 covering the floating gates 62. In addition, hard mask layers 67 are further formed on floating gates 62.

The hard mask layers 67 are used to form trenches for isolation and may be formed of a nitride layer (refer to FIGS. 5A and 5B). The remaining hard mask layer 67 may have a thickness of 10 Å to 200 Å.

If the hard mask layers 67 remain on the floating gates 52 as described above, a reduction in the upper width of the floating gate 52 can be prevented and so an electric field can be prevented from being concentrated on the upper portion of the floating gate 52. The hard mask layer may also be applied to other embodiments.

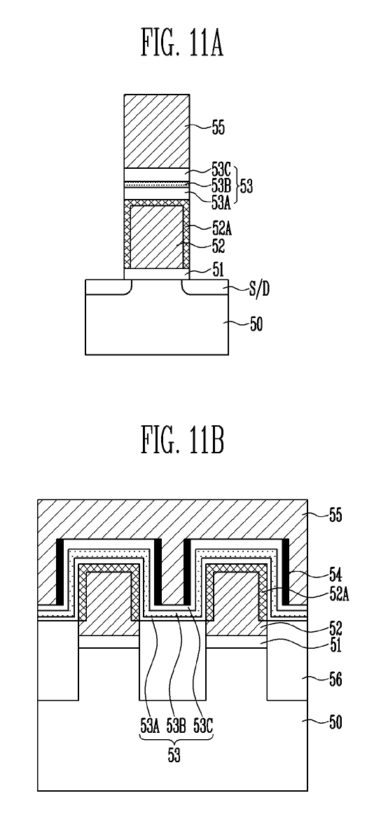

FIG. 13 is a cross-sectional view illustrating a floating gate type nonvolatile memory device having a 3-D structure according to an embodiment of the present invention.

As shown in FIG. 13, the floating gate type nonvolatile memory device having a 3-D structure according to an embodiment of the present invention includes a plurality of control gate electrodes 72 and a plurality of interlayer dielectric layers 71 which are alternately stacked over a substrate 70 and floating gates having the interlayer dielectric layers 71 buried in recessed regions. Furthermore, a charge blocking layer 74 and a barrier layer 73 are formed between the floating gates 75 and the control gate electrodes 72.

A method of manufacturing the floating gate type nonvolatile memory device according to an embodiment of the present invention is described below. First, the interlayer dielectric layers 71 and a conductive layer for control gate electrodes 72 are alternately formed over the substrate 70. A trench for a channel is formed by etching the interlayer dielectric layers 71 and the conductive layer. Regions for floating gates are formed by recessing the interlayer dielectric layers 71, exposed on the inner walls of the trench for a channel, to a certain depth. Next, the barrier layer 73 and the charge blocking layer 74 are formed on the surface of the trench for a channel. After the floating gates 75 are formed by filling the regions for the floating gates with a conductive material, the tunnel insulating layer 76 is formed on the inner walls of the trench for a channel. Next, the channel 77 is formed within the trench for a channel.

Accordingly, a plurality of memory cells, stacked along the channel 77 protruded from the substrate 70 and configured to have the barrier layer 73 formed between the charge blocking layer 74 and the control gate electrodes 72, is formed.

In some embodiments, the floating gate type nonvolatile memory device may be fabricated using sacrificial layers. First, after a plurality of interlayer dielectric layers and a plurality of sacrificial layers are alternately formed over a substrate, a trench for a channel is formed by etching the interlayer dielectric layers and the sacrificial layers. Floating gate regions are formed by recessing the interlayer dielectric layers, exposed on the inner walls of the trench for a channel, to a certain depth. Floating gates are formed by filling the floating gate regions with a conductive material. After a tunnel insulating layer is formed on the inner walls of the trench for a channel, a channel is formed of a material for the channel. After the trench is formed by etching the interlayer dielectric layers and the sacrificial layers, control gate electrode regions are formed by removing the sacrificial layers exposed on the inner walls of the trench. After a charge blocking layer and a barrier layer are formed along the surface of the trench, control gate electrodes are formed by filling the control gate electrode regions with a conductive material.

If the barrier layer 73 is formed in the floating gate type nonvolatile memory device having a 3-D structure as described above, the leakage current can be effectively blocked. Accordingly, the characteristics of the memory device can be improved.

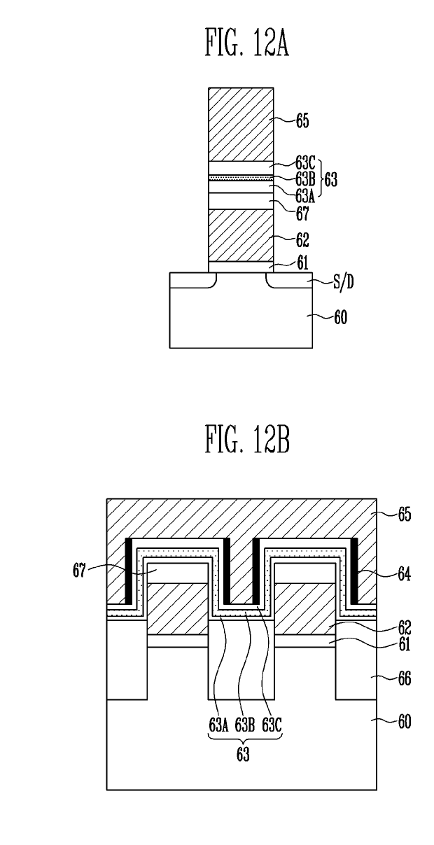

FIG. 14 is a graph showing the characteristics of materials which can be used as the barrier layer. In the X axis, numbers under the names of the materials denote dielectric constants. Bandgap energy and valance band offsets are shown in the Y axis.

As describe above, the barrier layer may be made of material having a greater valance band offset or a higher dielectric constant than the material of the charge blocking layer. In this case, the injection of holes can be effectively blocked.

The barrier layer may be made of material having a greater valance band offset or a higher dielectric constant than the material of an SiO₂ layer which is used as the upper oxide layer of a known charge blocking layer. An Al₂O₃ layer has a dielectric constant about 2.3 times greater than that of the SiO₂ layer. Accordingly, the coupling ratio of the Al₂O₃ layer is much high although the Al₂O₃ layer and the SiO₂ layer have the same physical thickness. Accordingly, if the barrier layer having a higher dielectric constant than the charge blocking layer is formed so as to secure a desired coupling ratio, the thickness of the charge blocking layer can be reduced as compared with a known art.

Furthermore, the Al₂O₃ layer has a lower bandgap than the SiO₂ layer by 0.2 eV, but has a greater valance band offset than the SiO₂ layer by 0.5 eV. Accordingly, a barrier margin for preventing holes from being injected into the charge blocking layer from the control gate electrode can be increased that much. Since the barrier layer having a greater valance band offset than the charge blocking layer 23 is formed as described above, the injection of holes can be efficiently blocked. Accordingly, the data retention characteristics and the cycling characteristics of the memory device can be improved.

That is, if the barrier layer formed of the Al₂O₃ layer is used in the floating gate type nonvolatile memory device, the total thickness of the charge blocking layer and the barrier layer is smaller than the thickness of a known charge blocking layer, but can have an increased barrier margin. Consequently, the coupling ratio of the floating gate type nonvolatile memory device can be increased and a program saturation phenomenon due to the leakage current can be prevented.

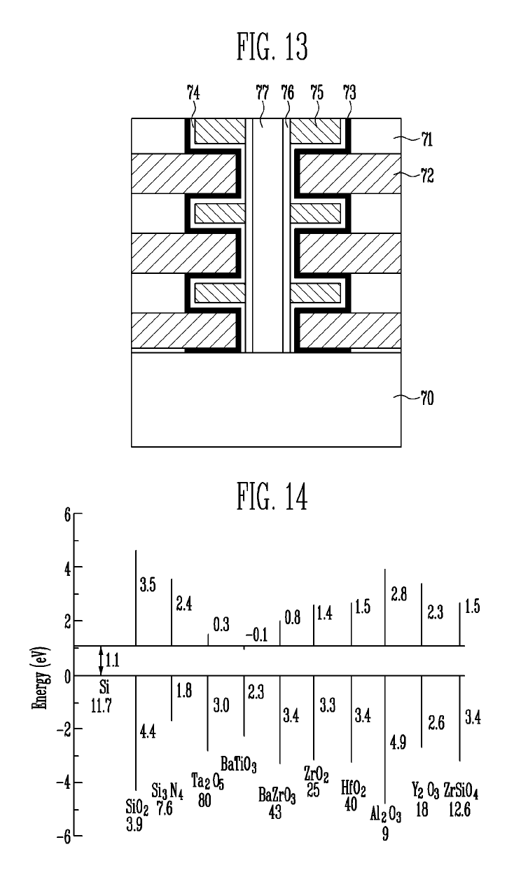

FIG. 15 shows an energy band diagram when the program operation of the floating gate type nonvolatile memory device is performed according to an exemplary embodiment of the present invention. FIG. 15 shows a change in the energy band when the program operation is performed.

In FIG. 15, solid lines relate to the devices according to exemplary embodiments of the present invention and indicate the energy band diagrams of the nitride layer, the upper oxide layer, and the barrier layer (N/O/Al₂O₃) of the charge blocking layer. Furthermore, dotted lines relate to known devices to which the barrier layer is not applied and indicate the energy band diagrams of the nitride layer and the upper oxide layer (N/O) of a charge blocking layer.

As shown in FIG. 15, if only the charge blocking layer is formed (refer to the dotted lines), a barrier margin is small because the upper oxide layer has a small valance band offset. Accordingly, holes are injected into the charge blocking layer from the control gate electrode. The injected holes pass through the upper oxide layer and then move to the nitride layer, thus recombined with charges trapped in the nitride layer. This lowers the bandgap energy of the lower oxide layer. Accordingly, electric charges stored in the floating gates continue to be discharged to the control gate electrode, thus generating a program saturation phenomenon.

However, if the barrier layer is formed as in an exemplary embodiments of the present invention (refer to the solid lines), the injection of holes from the control gate electrode can be blocked because a barrier margin is increased. Accordingly, injection of holes can be prevented.

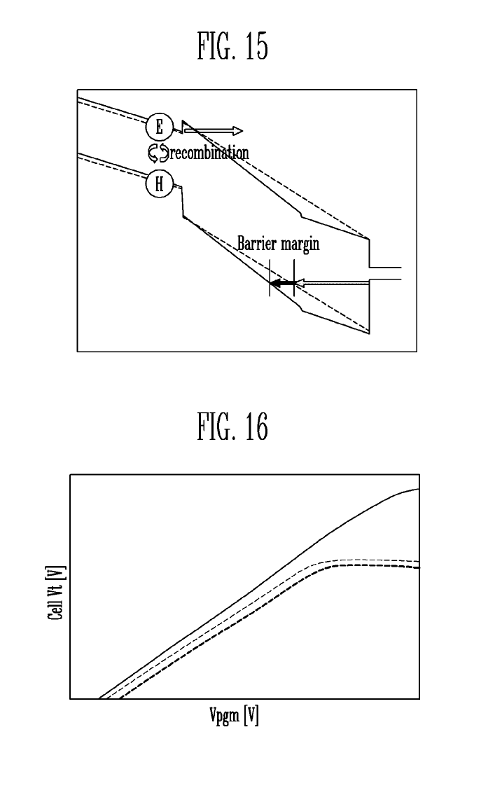

FIG. 16 is a graph showing a change in the threshold voltage of a memory cell when the program operation of the floating gate type nonvolatile memory device is performed according to an exemplary embodiment of the present invention. In FIG. 16, the X axis indicates a program voltage, and the Y axis indicates the threshold voltage of a programmed memory cell. Furthermore, a solid line indicates that the barrier layer according to an exemplary embodiments of the present invention has been applied, and a dotted line indicates that the barrier layer has not been applied.

From the graph, it can be seen that, if only the charge blocking layer has been formed (refer to the dotted line), a program saturation phenomenon in which the threshold voltage of the memory cell is no longer increased at a certain program voltage or higher is generated. However, it can be seen that, if the barrier layer according to an exemplary embodiments of the present invention is used (refer to the solid line), the program saturation phenomenon is not generated.

As described above, in the floating gate type nonvolatile memory device according to an exemplary embodiments of the present invention, the injection of holes from the control gate electrode to the charge blocking layer can be prevented by interposing the barrier layer between the charge blocking layer and the control gate electrode. Accordingly, although the thickness of the charge blocking layer is reduced, a problem in which holes within the control gate electrode are moved to the nitride layer of the charge blocking layer and then recombined with charges trapped in the nitride layer in a program operation can be prevented. That is, a program saturation phenomenon can be prevented.

In addition, if the barrier layer formed of the Al₂O₃ layer is used, the thickness of the charge blocking layer can be reduced. Accordingly, the coupling ratio can be improved and the program saturation phenomenon can also be effectively prevented.

What is claimed is:

1. A floating gate type semiconductor memory device, comprising:
a tunnel insulating layer;
a floating gate formed on the tunnel insulating layer;
a control gate electrode formed over the floating gate;
a charge blocking layer formed between the floating gate and the control gate electrode; and
a barrier layer formed in one or more areas of an area between the charge blocking layer and the control gate electrode and an area between the floating gate and the charge blocking layer.

2. The floating gate type nonvolatile memory device of claim 1, wherein the barrier layer is formed on only areas corresponding to both sidewalls of the floating gates.

3. The floating gate type semiconductor memory device of claim 1, wherein the charge blocking layer has a stack structure of a lower oxide layer, a nitride layer in the middle, and an upper oxide layer.

4. The floating gate type semiconductor memory device of claim 1, wherein the barrier layer is made of material having a greater valance band offset than material of the charge blocking layer.

5. The floating gate type semiconductor memory device of claim 1, wherein the barrier layer is made of material having a higher dielectric constant than material of the charge blocking layer.

6. The floating gate type semiconductor memory device of claim 1, wherein the barrier layer is formed of an Al₂O₃ layer.

7. The floating gate type semiconductor memory device of claim 1, wherein a surface of the floating gates is subjected to nitrification treatment process.

8. The floating gate type semiconductor memory device of claim 1, further comprising an oxide layer formed on the barrier layer.

9. The floating gate type semiconductor memory device of claim 1, further comprising a hard mask formed between the floating gate and the charge blocking layer formed on the respective floating gates.

10. The floating gate type semiconductor memory device of claim 1, wherein the charge blocking layer has a thickness of 30 Å to 300 Å.

11. The floating gate type semiconductor memory device of claim 1, wherein the barrier layer has a thickness of 1 Å to 50 Å.

12. The floating gate type semiconductor memory device of claim 1, wherein a total thickness of the charge blocking layer and the barrier layer is 30 Å to 350 Å.

13. A method of manufacturing a floating gate type semiconductor memory device, the method comprising:
forming a tunnel insulating layer and a conductive pattern for a floating gate over a substrate;
forming a charge blocking layer on a surface of resultant structure in which the conductive pattern for the floating gate is formed;
forming a conductive layer for a control gate electrode over the charge blocking layer; and
forming a barrier layer after forming the conductive patterns for the floating gate or after forming the charge blocking layer.

14. The method of claim 13, wherein forming the barrier layer comprises:
forming the barrier layer on a surface of resultant structure in which the conductive pattern for the floating gate is formed or resultant structure in which the charge blocking layer is formed; and
etching the barrier layer so that the barrier layer remains on areas corresponding to the sidewall of the conductive pattern for the floating gate.

15. The method of claim 13, wherein forming the charge blocking layer comprises sequentially forming a lower oxide layer, a nitride layer in the middle, and an upper oxide layer.

16. The method of claim 13, further comprising forming an oxide layer on the barrier layer, after forming the barrier layer.

17. The method of claim 13, wherein the barrier layer is made of material having a greater valance band offset than material of the charge blocking layer.

18. The method of claim 13, wherein the barrier layer is made of material having a higher dielectric constant than material of the charge blocking layer.

19. The method of claim 13, wherein the barrier layer is formed of an Al₂O₃ layer.

20. The method of claim 13, wherein a surface of the conductive patterns for floating gates is subjected to nitrification treatment process, after forming the tunnel insulating layer and the conductive patterns for the floating gate.

21. The method of claim 20, wherein the nitrification treatment process is performed through a plasma nitrification process using an Ar gas and an N₂ gas under condition that temperature is 400 to 600° C., pressure is 0.1 to 0.2 Torr, and power of 1000 to 2000 W.

22. The method of claim 13, wherein forming the tunnel insulating layer and the conductive pattern for the floating gate comprises:
forming the tunnel insulating layer and a conductive layer for the floating gate over the substrate;
forming a hard mask pattern on the conductive layer for the floating gate;
etching the conductive layer for the floating gate, the tunnel insulating layer, and the substrate by using the hard mask patterns as an etch barrier, thereby forming a trench for isolation; and
forming an isolation layer by filling the trenches for isolation with an insulating material.

23. The method of claim 22, wherein when forming the charge blocking layer, the charge blocking layer is formed with a hard mask remained on the conductive patterns for the floating gate.

24. The method of claim 13, further comprising etching the barrier layer so that the barrier layer remains on only areas corresponding to the sidewalls of the conductive patterns for the floating gate, after forming the barrier layer.

25. The method of claim 13, further comprising performing a thermal treatment process, after forming the barrier layer.

26. The method of claim 25, wherein the thermal treatment process is performed in a temperature range of 700 to 1100° C. using a furnace or a rapid thermal annealing (RTA) method.
